(19) United States
(12) Patent Application Publication
(10) Pub. No.: US 2026/0293682 A1
(43) Pub. Date: Sep. 24, 2026

(54) SEMICONDUCTOR DEVICE

(71) Applicant: Kioxia Corporation, Tokyo (JP)

(72) Inventor: Satoru TAKAKU, Yokohama (JP)

(73) Assignee: Kioxia Corporation, Tokyo (JP)

(21) Appl. No.: 19/328,255

(22) Filed: Sep. 15, 2025

(30) Foreign Application Priority Data
Mar. 18, 2025 (JP) 2025-043649

(51) Int. Cl. H01L 23/00; H01L 21/48; H01L 23/498; H01L 25/065

(52) U.S. Cl. CPC H10W 42/121; H10W 70/093; H10W 70/685; H10W 90/00; H10W 90/401; H10W 90/701; H10W 90/24; H10W 90/291; H10W 90/754

(57) ABSTRACT

A semiconductor device that can restrain a crack at a joint interface of a solder ball is provided. According to one embodiment, a semiconductor device includes: a wiring substrate having a support surface on which a semiconductor chip is to be mounted and including an electrode and a first land portion on a first surface, opposite the support surface, of the wiring substrate. The first land portion is electrically connected to the electrode. A plurality of first bumps protrudes from the first land portion. A solder ball is on the first land portion and buries the plurality of first bumps.

### CROSS-REFERENCE TO RELATED APPLICATION

This application is based upon and claims the benefit of priority from Japanese Patent Application No. 2025-043649, filed Mar. 18, 2025, the entire contents of which are incorporated herein by reference.

### FIELD

Embodiments described herein relate generally to a semiconductor device.

### BACKGROUND

For example, there is a semiconductor device that is used while being connected with a mounting substrate by a solder ball. When a crack is generated, for example, at a joint interface between the solder ball and the semiconductor device side, the electric conduction between the semiconductor device and the mounting substrate is not obtained in some cases.

### BRIEF DESCRIPTION OF THE DRAWINGS

FIG. 1 is a schematic sectional view showing an exemplary configuration of a semiconductor system in an embodiment 1.

FIG. 2 is a plan view showing the configuration of a lower surface of a wiring substrate in the embodiment 1.

FIG. 3 is an enlarged sectional view taken from line AA of FIG. 2.

FIG. 4 is a diagram serially illustrating a part of the procedure of a production method for a semiconductor package in the embodiment 1.

FIG. 5 is a diagram for describing an example of a crack in a solder ball that is generated in a semiconductor package in a comparative example.

FIG. 6 is a diagram for describing an example of a crack in the solder ball that is generated in the semiconductor package in the comparative example and the semiconductor package in the embodiment side by side.

FIG. 7 is a diagram for describing a modification 1 of the embodiment 1.

FIG. 8 is a diagram for describing a modification 2 of the embodiment 1.

FIG. 9 is a diagram for describing a modification 3 of the embodiment 1.

FIG. 10 is a diagram for describing a modification 4 of the embodiment 1.

FIG. 11 is a diagram for describing the modification 4 of the embodiment 1.

FIG. 12 is an enlarged sectional view showing an exemplary configuration of a part of a semiconductor system in an embodiment 2.

FIG. 13 is a diagram for describing a modification of the embodiment 2.

### DETAILED DESCRIPTION

One embodiment is directed to providing a semiconductor device that can restrain a crack at a joint interface of a solder ball.

In general, according to one embodiment, a semiconductor device includes: a wiring substrate; and a semiconductor chip that is placed on the wiring substrate, in which the wiring substrate includes a first land portion that is disposed on a first surface and that is electrically connected with the semiconductor chip, the first surface being a surface on an opposite side of a surface on which the semiconductor chip is placed, a plurality of first bumps that protrudes from the first land portion, and a solder ball that is disposed on the first land portion and in which the plurality of first bumps is buried.

Embodiments will be described below in detail with reference to the drawings. The present disclosure is not limited to the following embodiments. Further, constituent elements in the following embodiments include elements that can be easily conceived by a person skilled in the art, or substantially identical elements.

### Embodiment 1

### Exemplary Configuration of Semiconductor Package

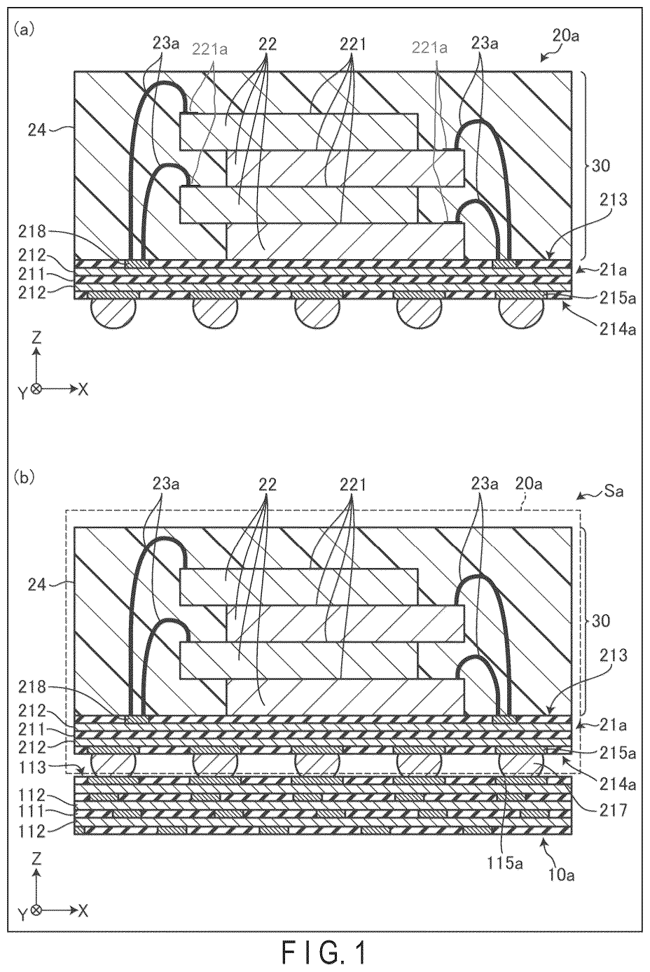

FIG. 1 is a schematic sectional view showing an exemplary configuration of a semiconductor system Sa in an embodiment 1. More specifically, part (a) of FIG. 1 is a sectional view of a semiconductor package 20a, and part (b) of FIG. 1 is a sectional view of a semiconductor system Sa in which the semiconductor package 20a is mounted on a mounting substrate 10a.

The semiconductor package 20a is an example of the semiconductor device. The whole of the semiconductor system Sa including the semiconductor package 20a and the mounting substrate 10a may be regarded as a semiconductor device.

In the present specification, in the semiconductor system Sa, the side of the semiconductor package 20a is an upper side, the side of the mounting substrate 10a is a lower side, and the top-bottom direction of the semiconductor system Sa is referred to as a Z-direction. Further, directions orthogonal to the Z-direction are an X-direction and a Y-direction. The X-direction and the Y-direction are directions along a lower surface of the semiconductor package 20a, and the X-direction and the Y-direction are orthogonal to each other. Further, a side to which the arrow of each axis is oriented is a positive direction, and the opposite side is a negative direction.

As shown in the part (a) of FIG. 1, the semiconductor package 20a as the semiconductor device includes a wiring substrate 21a, a plurality of semiconductor chips 22 that is placed on the wiring substrate 21a, wires 23a that connect the wiring substrate 21a and the plurality of semiconductor chips 22, solder balls 217 that are provided on a lower surface of the wiring substrate 21a, and a mold material 24 that seals the semiconductor chips 22.

The wiring substrate 21a is configured as a multi-layer substrate in which insulating layers 211 and conductive layers 212 are alternately stacked multiple times. The wiring substrate 21a includes an electrode 218 on an upper surface 213 that is a surface on which the plurality of semiconductor chips 22 is placed, e.g., a support surface, and land portions 215a on a lower surface 214a on the opposite side of the upper surface 213. Other than the electrode 218, the upper surface 213 is insulating. The land portion 215a is a conductive portion from which the plurality of semiconductor chips 22 are electrically connected to other external elements and may have a larger surface area than the electrode 218. The lower surface 214a is an example of the first surface, and the land portion 215a is an example of the first land portion.

For example, the insulating layer 211 is composed of carbon fiber, fiberglass, aramid fiber, or the like that has been impregnated with a thermosetting resin such as epoxy resin before hardening. For example, the conductive layer 212 and the electrode 218 are composed of a metal such as Cu (copper). The conductive layer 212 includes a wiring pattern, and is connected with the electrode 218 provided on the upper surface 213 and the land portion 215a provided on the lower surface 214a. The wire 23a is connected with the electrode 218.

For example, the wire 23a is configured to contain at least one metal material of Au, Cu, Pd, and Ag. A first end of the wire 23a is connected with the electrode 218, and a second end of the wire 23a is connected with a principal surface 221 of one of the plurality of semiconductor chips 22. Thereby, the plurality of semiconductor chips 22 and the land portion 215a are electrically connected.

Each of the plurality of semiconductor chips 22 is one of small pieces into which a Si substrate or the like is divided, and for example, includes an semiconductor element on the principal surface 221 side. For example, the semiconductor element is a non-volatile memory such as a NAND flash memory. The plurality of semiconductor chips 22 is sequentially stacked so as to deviate, e.g., having a center thereof offset, from each other in the X-direction, such that each principal surface 221 is oriented upward. Thereby, at an end portion of one side of the principal surface 221 of an individual semiconductor chip 22, there is a portion that does not overlap with a semiconductor chip 22 directly above the individual semiconductor chip 22. At this portion and an end portion of one side of the principal surface 221 of a semiconductor chip 22 at the uppermost layer, electrode pads 221a are provided, which are connected to the electrode 218 via the wires 23a.

An adhesive layer may be provided on a surface on the opposite side of each principal surface 221 of the plurality of semiconductor chips 22, that is, on a lower surface. Thereby, the plurality of semiconductor chips 22 is fixed to each other.

The mold material 24 is a resin material that seals the plurality of semiconductor chips 22 and the wires 23a. Hereinafter, the mold material 24, the plurality of semiconductor chips 22 and the wires 23a that are sealed by the mold material 24 are sometimes collectively referred to as a sealing portion 30. That is, the sealing portion 30 is a portion that is disposed on the upper surface 213 of the wiring substrate 21a.

As described above, the wiring substrate 21a includes the land portion 215a on the lower surface 214a. The land portion 215a is configured to contain Cu. By containing Cu, the hardness of the land portion 215a may be increased. However, without being limited to Cu, the land portion 215a may be configured to contain, for example, Au, Ag, or the like.

The wiring substrate 21a includes the solder ball 217 on the lower surface of the land portion 215a. The solder ball 217 is a solder that is formed in a ball shape, and is configured to contain Sn (tin) and the like. The diameter of the solder ball 217 is about 300 um. The solder ball 217 has such a size, and therefore, a plurality of later-described bumps 216a formed on the land portion 215a can be buried in the solder ball 217, e.g., cover all exposed portions of the bumps. When the solder ball 217 is formed on the wiring substrate 21a, molten solder is attached to the land portion 215a, and then Cu ions leaked from the land portion 215a are supplied into the solder ball 217. Thereby, the hardness of the solder ball 217 is increased.

In this way, the solder ball 217 is connected with the land portion 215, at the upper end portion, and is connected with the mounting substrate 10a, at the lower end portion, and thereby, the semiconductor system Sa is configured.

As shown in the part (b) of FIG. 1, for example, the semiconductor system Sa has a configuration in which the semiconductor package 20a having the plurality of semiconductor chips 22 placed is mounted on the mounting substrate 10a.

The mounting substrate 10a is disposed so as to face the lower surface 214a of the wiring substrate 21a. The mounting substrate 10a is configured as a multi-layer substrate in which insulating layers 111 and conductive layers 112 are alternately stacked multiple times. The mounting substrate 10a includes land portions 115a on an upper surface 113 that is a surface that faces the wiring substrate 21a. The land portions 115a may be recessed from the upper surface 113. The land portion 115a is connected with the lower end portion of the solder ball 217. The land portion 115a is an example of the second land portion.

For example, the insulating layer 111 is composed of carbon fiber, fiberglass, aramid fiber, or the like that has been impregnated with a thermosetting resin such as epoxy resin before hardening. For example, the conductive layer 112 is configured to contain Cu. The conductive layer includes a wiring pattern, and is connected with the land portion 115a provided on the upper surface 113 of the mounting substrate 10a. Thereby, the plurality of semiconductor chips 22 and the mounting substrate 10a are electrically connected through the solder ball 217.

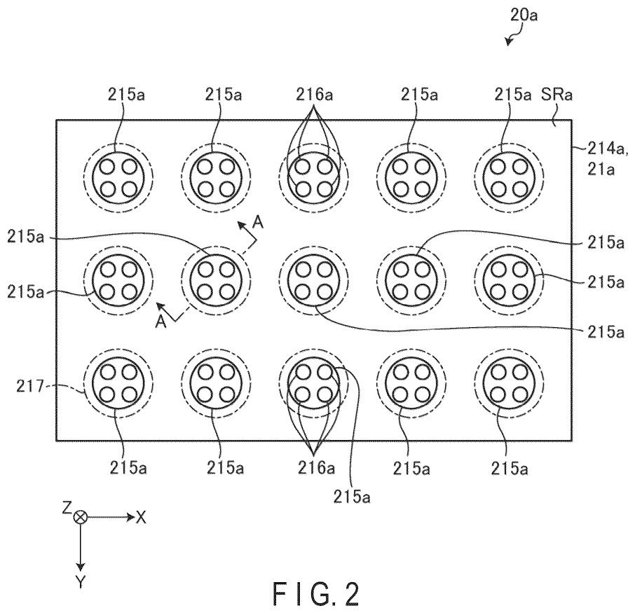

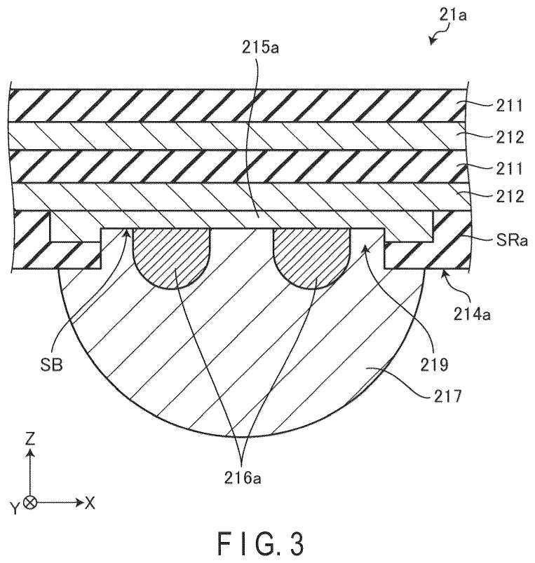

Next, details of the configuration of the wiring substrate 21a will be described with use of FIG. 2 and FIG. 3.

FIG. 2 is a plan view showing the configuration of the lower surface 214a of the wiring substrate 21a in the embodiment 1. FIG. 2 is a diagram of the lower surface 214a of the wiring substrate 21a as viewed from the negative side in the Z-direction. In FIG. 2, the solder ball 217 is shown by a dashed-dotted line. In FIG. 2, for explanatory convenience, the land portion 215a under the solder ball 217 and the plurality of later-described bumps 216a, which are actually invisible, are shown by solid lines. Further, FIG. 3 is an enlarged sectional view taken from line AA of FIG. 2.

FIG. 2 and FIG. 3 show only the semiconductor package 20a before the semiconductor package 20a is mounted on the mounting substrate 10a.

As shown in FIG. 2, the wiring substrate 21a includes a plurality of land portions 215a on the lower surface 214a. The plurality of land portions 215a is disposed on the lower surface 214a of the wiring substrate 21a in a matrix manner. The plurality of bumps 216a is formed on each of the plurality of land portions 215a. The bump 216a is an example of the first bump. Each of the plurality of bumps 216a may include Cu.

The plurality of bumps 216a is disposed on each of the plurality of land portions 215a. In the example of FIG. 2, four bumps 216a are provided on the individual land portion 215a, and the bumps 216a are disposed two by two along the X-direction and the Y-direction at roughly regular intervals. Further, the plurality of bumps 216a is disposed so as to exist only on the surface of the individual land portion 215a, as viewed from the negative side in the Z-direction.

As shown in FIG. 3, for example, the individual land portion 215a is provided so as to protrude from the lower surface of a conductive layer 212 that is the lowermost layer of the wiring substrate 21a having a plurality of layers. An outer edge portion of the individual land portion 215a is covered with a solder resist SRa. That is, each center surface of the plurality of land portions 215a is exposed from an opening portion of the solder resist SRa. A surface SB of the individual land portion 215a that is exposed from the opening portion, e.g. an exposed surface, of the solder resist SRa has a concave portion 219 that dents to the positive side in the Z-direction relative to the portion covered with the solder resist SRa. That is, the surface SB is a bottom surface of the concave portion 219, is recessed relative to the lower surface 214a, and is an example of the second surface.

The plurality of bumps 216a is provided so as to protrude from the surface SB of the individual land portion 215a to the negative side in the Z-direction. That is, one end portion of each of the plurality of bumps 216a is connected with the surface SB of the land portion 215a, and the other end portion extends to the negative side in the Z-direction, e.g., beyond the lower surface 214a along the negative Z-direction. For example, the diameter and height of the plurality of bumps 216 a are 100 um or less.

The plurality of bumps 216a is disposed along the surface SB of the individual land portion 215a. In the example of FIG. 2, it has been described that the four bumps 216a provided on the individual land portion 215a are disposed so as to exist only on the surface of the individual land portion 215a. More specifically, the plurality of bumps 216a is disposed so as to exist on the inside of the surface SB of the individual land portion 215a, as viewed from the negative side in the Z-direction.

The plurality of bumps 216a is buried in the solder ball 217 provided at a position that overlaps with the land portion 215a. Specifically, the plurality of bumps 216a is contained in the solder ball 217. However, without being limited to the example of FIG. 3, in the buried state, for example, a state where solder is attached to the whole of the surfaces of the plurality of bumps 216a is included. Further, a state where solder is attached to parts of the surfaces of the plurality of bumps 216a is included. As described above, the diameter of the solder ball 217 is about 300 um, and each of the diameter and height of the individual bump 216a is 100 um or less. The plurality of bumps 216a can be easily buried in the solder ball 217. For example, the solder ball 217 may overlap an entirety of the dent 219 and a portion of the lower surface 214a without being limited to the example of FIG. 3,

### Production Method for Semiconductor Package

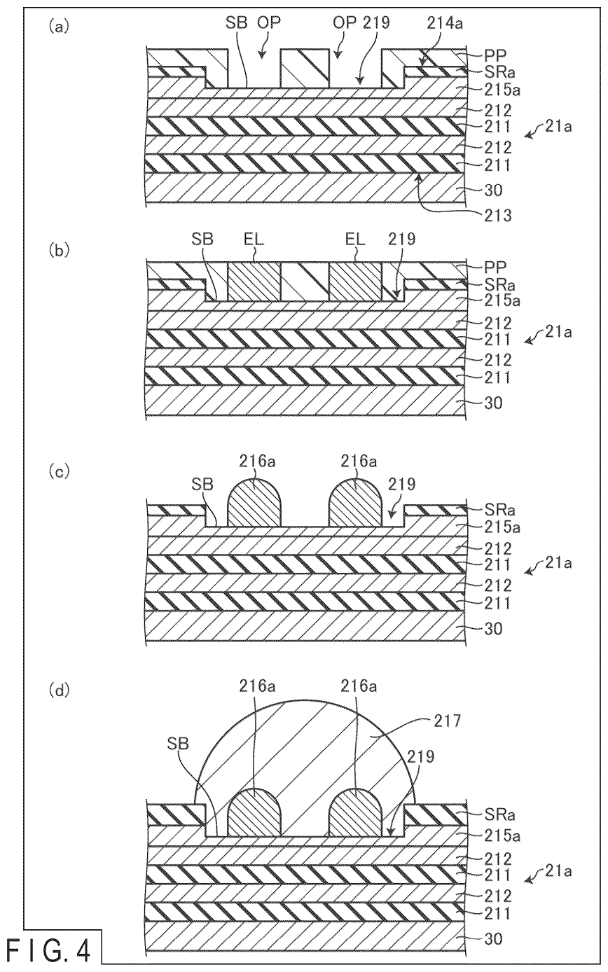

FIG. 4 is a diagram serially illustrating a part of the procedure of a production method for the semiconductor package 20a in the embodiment 1.

In the production method for the semiconductor package 20a, before the process in part (a) of FIG. 4, the sealing portion 30 is previously formed on the upper surface 213 of the wiring substrate 21a. In parts (a) to (d) of FIG. 4, enlarged sectional views including the lower surface 214a of the wiring substrate 21a are shown, and some constituents such as the sealing portion 30 formed on the upper surface 213 of the wiring substrate 21a are not illustrated. Further, in parts (a) to (d) of FIG. 4, the lower surface 214a of the wiring substrate 21a is shown so as to be oriented upward on the sheet plane, for showing processes for the lower surface 214a of the wiring substrate 21a, as exemplified by the formation of the bump 216a and the solder ball 217.

As shown in part (a) of FIG. 4, the land portion 215a that is connected with the conductive layer 212 and whose outer edge portion is covered with the solder resist SRa is formed on the lower surface 214a of the wiring substrate 21a. On the wiring substrate 21a on which a part of the land portion 215a is opened in this way, a naturally oxidized film on the surface of the land portion 215a is removed, and thereafter, a predetermined surface treatment including the application of an organic coat (not illustrated) such as an OSP (Organic Solder Preservative) are performed on the land portion 215a, for preventing further oxidation of Cu, and the like.

The organic coat does not have conductivity, and therefore, is removed for forming the solder ball 217 and the like on the land portion 215a. Before the formation of the organic coat, the naturally oxidized film is removed from the opening portion on the solder resist SRa, and thereby, the vicinity of the center of the land portion 215a dents, so that the concave portion 219 whose bottom surface is the surface SB is formed.

The land portion 215a does not always need to have a shape in which the vicinity of the center dents as illustrated in part (d) of FIG. 4 and the like. For example, by forming a plated layer such as a Ni/Au plated layer at the concave portion 219, the land portion 215a may have a shape in which the portion of the formation of the plated layer such as a Ni/Au plated layer rises relative to the surface of the other portion of the land portion 215a. The plated layer may contain an alloy.

Next, a resist pattern PP is formed on the land portion 215a. The resist pattern PP is formed so as to include a plurality of opening portions OP at positions that overlap with the concave portion 219 of the land portion 215a. The surface SB of the land portion 215a is exposed from the plurality of opening portions OP.

Next, as shown in part (b) of FIG. 4, a plated layer EL that covers the surface SB of the land portion 215a that is exposed on the plurality of opening portions OP is formed by an electroplating method, for example. The plated layer EL contains Cu or the like. At this time, the plated layer EL may be partially formed also on the resist pattern PP.

Next, the resist pattern PP is removed by a liftoff method or the like. Thereby, as shown in part (c) of FIG. 4, the bumps 216a are formed at regions that respectively correspond to the plurality of opening portions OP.

Next, as shown in part (d) of FIG. 4, the solder ball 217 is formed at a position that overlaps with the land portion 215a. The solder ball 217 is formed using a mass reflow technique of melting a plurality of solders arranged in an array manner and forming a plurality of solder balls 217 at one time, for example.

At this time, as described above, Cu ions leaked from the land portion 215a are mixed in the solder ball 217, so that the hardness of the solder ball 217 is increased.

Alternatively, the solder ball 217 may be formed using a thermal compression bonding technique or an ultrasonic bonding technique.

Thus, the production of the semiconductor package 20a is finished.

When the semiconductor package 20a after the above-described production process is mounted on the mounting substrate 10a (FIG. 1), the semiconductor package 20a is picked up such that the side of the solder balls 217 is the lower side, and the solder ball 217 is caused to face the mounting substrate 10a. Next, the land portion 115a (FIG. 1) of the mounting substrate 10a and the solder ball 217 overlap in the top-bottom direction, and are heated to 100° C. or higher by an oven or the like. Thereby, the land portion 115a and the solder ball 217 are joined, and the mounting substrate 10a and the semiconductor package 20a are electrically connected.

Thus, the production of the semiconductor system Sa is finished.

### Overview

For prolonging the life of the semiconductor package, it is desired that the semiconductor package has a high resistance against thermal stress under a high-temperature or low-temperature environment. For evaluating the resistance against thermal stress, for example, a temperature cycling test (TCT) is performed before the shipment of the semiconductor package 20a.

When the semiconductor package 20a and the mounting substrate 10a are under the high-temperature or low-temperature environment, the mounting substrate 10a and the semiconductor package 20a expand or contract depending on the respective thermal expansion coefficients. When the cycle of the temperature change between the high temperature and the low temperature is repeated, for example, the semiconductor package 20a sometimes bends downward due to the expansion difference and contraction difference between the mounting substrate 10a and the semiconductor package 20a. Thereby, there is fear that stress is applied, particularly, to a solder ball 217 disposed on the outer edge portion side of the semiconductor package 20a and a crack is generated at the joint interface between the solder ball 217 and the land portion 215a.

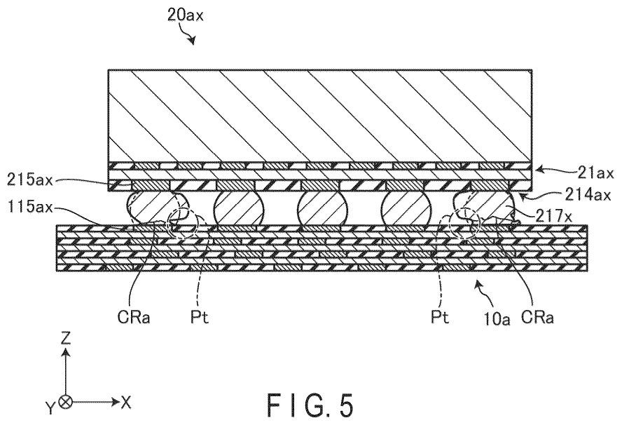

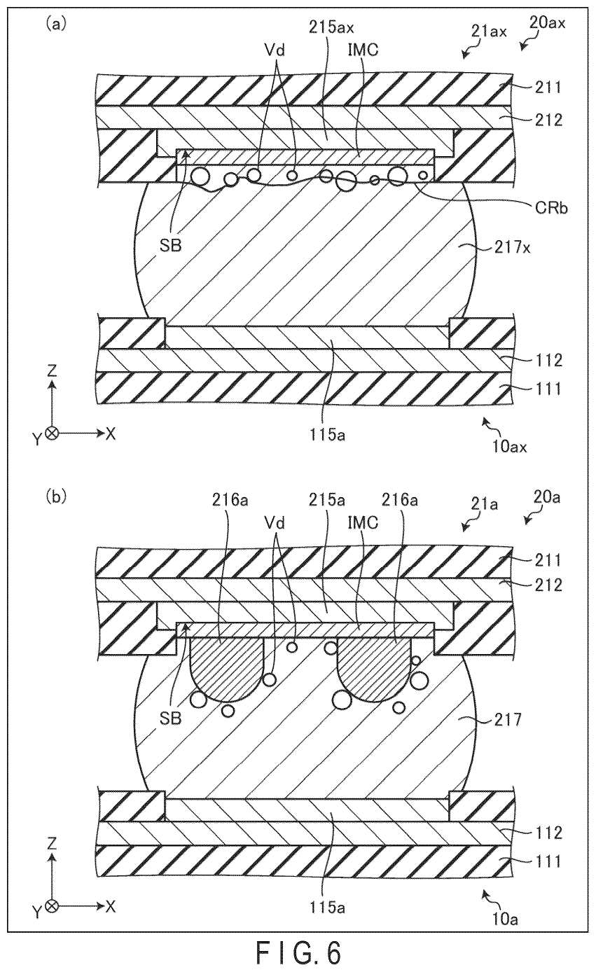

Next, examples of the generation of the crack in a solder ball 217x in a semiconductor package 20ax in a comparative example will be described with use of FIG. 5 to FIG. 6. The crack in the solder ball 217x is generated by various causes including the above-described temperature change cycle.

FIG. 5 is a diagram for describing an example of the crack in the solder ball 217x that is generated in the semiconductor package 20ax in the comparative example. The crack described with FIG. 5 is a crack that involves the deformation of the solder ball 217x. In the example of FIG. 5, the deformation occurs in solder balls 217x disposed on the outer edge side of the semiconductor package 20a. The shapes of the solder balls 217x after the deformation are shown by solid lines, and the shapes of the solder balls 217x before the deformation are shown by chain lines.

For example, when local stress is applied to the solder ball 217x by the cycle of the temperature change, a crystal grain at a spot that receives the stress is sometimes coarsened. When the coarsening of the crystal grain progresses, the interface of a fine grain of the solder ball 217x is pulled by the coarsened grain, and the solder ball 217x is sometimes deformed in the direction of the progress of the coarsening. Further, the coarsening of the crystal grain sometimes decreases the hardness of the spot of the coarsening.

For example, suppose that the coarsening of the crystal grain progresses at a portion Pt of the lower end portion of the solder ball 217x disposed on the outer edge portion side of the semiconductor package 20a as shown in FIG. 5. The portion Pt is a portion that is of the lower end portion of the solder ball 217x and that is oriented to the inside of the semiconductor package 20ax. As the result of the progress of the coarsening of the crystal grain at the portion Pt, the solder ball 217x is deformed toward the inside of the semiconductor package 20ax.

Since the solder ball 217x is deformed toward the inside of the semiconductor package 20ax, each of the area of a joint surface between the solder ball 217x and a land portion 215ax and the area of a joint surface between the solder ball 217x and the land portion 115ax is decreased. When the cycle of the temperature change is further repeated in a state where the areas of the joint surfaces have been decreased, a crack CRa is sometimes generated near the interface between the solder ball 217x and the land portion 115ax, for example. The crack CRa grows in a direction along a lower surface 214ax.

Next, an example of the generation of a second crack will be described with use of FIG. 6. The second crack is a crack that is generated by voids Vd formed in the solder ball 217x.

FIG. 6 is a diagram for describing an example of the crack in the solder ball 217x that is generated in the semiconductor package 20ax in the comparative example and the semiconductor package 20a in the embodiment side by side. More specifically, part (a) of FIG. 6 shows an example of the crack in the solder ball 217x that is generated in the semiconductor package 20ax in the comparative example, and part (b) of FIG. 6 shows the state of the periphery of the solder ball 217 in the semiconductor package 20a in the embodiment.

As shown in part (a) of FIG. 6, a compound layer IMC is formed at a portion of the solder ball 217x near the interface with the land portion 215ax. The compound layer IMC is a layer that is formed by the alloying of Cu supplied from the land portion 215ax and Sn (tin) in the solder ball 217x.

A plurality of voids Vd that is arrayed along the compound layer IMC in a perforated manner is sometimes formed at a portion of the solder ball 217x under the compound layer IMC. The voids Vd are formed in the production process for the semiconductor package 20ax. When the cycle of the temperature change is repeated in a state where the plurality of voids Vd is formed, a crack CRb that passes through the plurality of voids Vd is sometimes generated.

For restraining the above-described crack in the solder ball, the wiring substrate 21a of the semiconductor package 20a in the embodiment is provided with the plurality of bumps 216a that protrudes from the land portion 215a. The plurality of bump 216a is buried in the solder ball 217 disposed on the land portion 215a.

Thereby, the plurality of bumps 216a functions as a stopper of the solder ball 217, and the deformation of the solder ball 217 shown in FIG. 5 is restrained. As a result, it is possible to restrain the decrease in the area of contact surfaces of the solder ball 217 and the land portion 215a, and therefore, it is possible to restrain the crack CRa in the solder ball 217.

Further, the plurality of bumps 216a is configured to contain Cu, and therefore, Cu ions are supplied from the plurality of bumps 216a into the solder ball 217. Thereby, it is possible to restrain the decrease in the hardness of the solder ball 217. As a result, it is possible to restrain the crack in the solder ball 217.

Further, as shown in part (b) of FIG. 6, since the plurality of bumps 216a protrudes from the land portion 215a, the compound layer IMC is formed along surfaces of the plurality of bumps 216a. Therefore, the plurality of voids Vd is also arrayed along surfaces of the plurality of bumps 216a. In this way, the voids Vd are avoided from being arrayed along a predetermined direction, and therefore, it is hard for the crack CRb passing through the voids Vd to be generated. Further, even when the crack CRb is generated, the plurality of bumps 216a functions as a stopper, and can restrain the growth of the crack CRb.

In the above-described embodiment 1, the plurality of bumps 126a is formed by the electroplating method or the like. However, the bumps 126a may be formed by another method. As an example, the plurality of bumps 126a may be formed by a wire bonding in which a capillary or the like is used.

### Modification 1

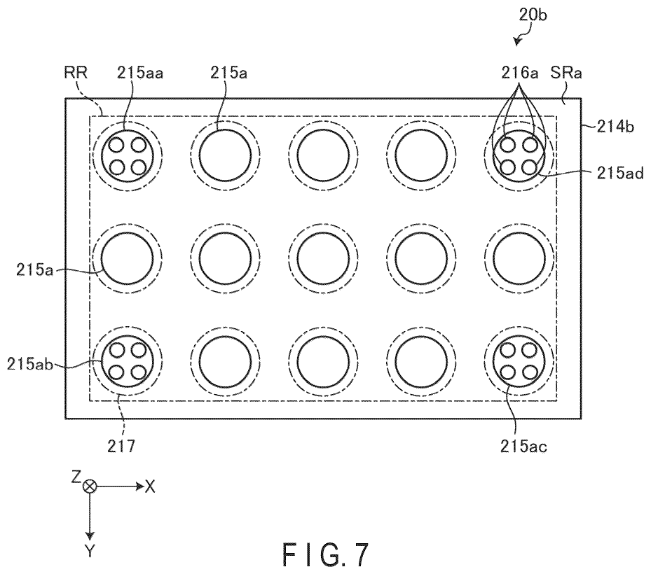

A modification 1 of the embodiment 1 will be described below with reference to FIG. 7. A semiconductor package 20b in the modification 1 is different from the above-described embodiment 1 in the number and positions of land portions 215a provided with the plurality of bumps 216a. In the following description, the same constituents as those in the above-described embodiment 1 are denoted by the same reference characters, and descriptions thereof are sometimes omitted.

FIG. 7 is a diagram for describing the modification 1 of the embodiment 1. FIG. 7 is a plan view showing the configuration of a lower surface 214b of the semiconductor package 20b in the modification 1, and is a diagram corresponding to FIG. 2.

The plurality of bumps 216a is provided on land portions 215a that are disposed at an outer edge portion of a disposition region RR for a plurality of land portions 215a disposed in a matrix manner. In the example of FIG. 7, the plurality of bumps 216a is provided on each of four land portions 215aa to 215ad that are disposed at four corners of the disposition region RR.

As described above, the stress that is applied to the solder ball 217 disposed on the outer edge side of the semiconductor package 20b is higher than the stress that is applied to the solder ball 217 disposed on the inside. Therefore, by selectively providing the plurality of bumps 216a on the land portions 215aa to 215ad, it is possible to restrain the crack in the solder ball 217 with high efficiency.

In addition, the semiconductor package 20b in the modification 1 exerts the same effect as the semiconductor package 20a in the above-described embodiment 1.

### Modification 2

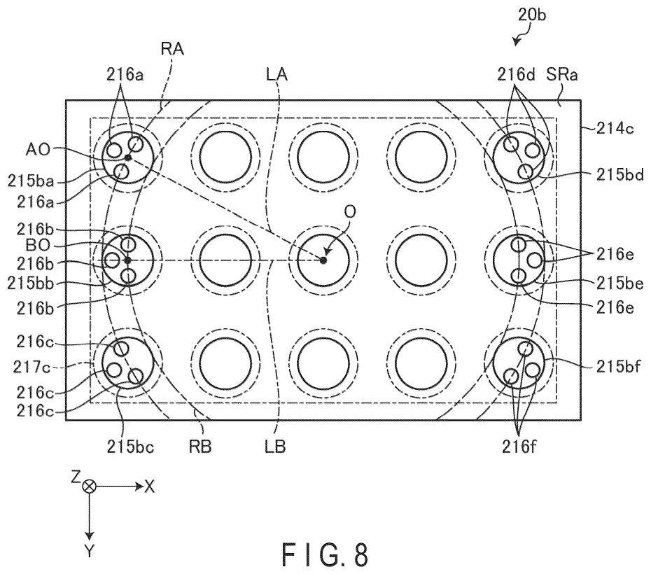

A modification 2 of the embodiment 1 will be described below with reference to FIG. 8. A semiconductor package 20c in the modification 2 is a modification of the semiconductor package 20b in the modification 1, and is different from the above-described modification 1 in the number and positions of bumps 216a that are disposed on one land portion 215a. In the following description, the same constituents as those in the above-described embodiment 1 and the modification 1 are denoted by the same reference characters, and descriptions thereof are sometimes omitted.

FIG. 8 is a diagram for describing the modification 2 of the embodiment 1. FIG. 8 is a plan view showing the configuration of a lower surface 214c of a semiconductor package 20c in the modification 2 of the embodiment 1, and is a diagram corresponding to FIG. 2.

As shown in FIG. 8, the plurality of bumps 216a is provided on land portions 215a that are disposed at the outer edge portion of the disposition region RR. Specifically, the plurality of bumps 216a is provided on each of land portions 215ba to 215bf that are arrayed along the Y-direction at outer edge portions on the positive and negative sides in the X-direction in threes.

Three bumps 216a, three bumps 216b, three bumps 216c, three bumps 216d, three bumps 216e, and three bumps 216f are formed on the land portions 215ba to 215bf, respectively. The three bumps 216a, the three bumps 216b, the three bumps 216c, the three bumps 216d, the three bumps 216e, and the three bumps 216f are disposed at positions away from a central portion O of the lower surface 214c, on the land portions 215ba to 215bf.

For example, the three bumps 216a provided on the land portion 215ba are disposed at positions away from the central portion O in a region on the inside of the land portion 215ba.

In other words, the three bumps 216a are formed at positions other than a straight line LA between the central portion O and a central portion AO of the land portion 215ba. Furthermore, in other words, the three bumps 216a are formed on the circumference of a circle RA whose center is the central portion O and whose radius is the straight line LA, and at a position on the outside of the circumference of the circle RA.

Further, for example, the three bumps 216b are disposed on the land portion 215bb. The three bumps 216b are also disposed at positions away from the central portion O in a region on the inside of the land portion 215bb.

In other words, the three bumps 216b are formed at positions other than a straight line LB between the central portion O and a central portion BO of the land portion 215bb. Furthermore, in other words, the three bumps 216b are formed on the circumference of a circle RB whose center is the central portion O and whose radius is the straight line LB, and at a position on the outside of the circumference of the circle RB.

In addition, the content about the dispositions of the bumps 216a, 216b of the land portions 215ba, 215bb is applied to the dispositions of the respective bumps 216c to 216f of the other land portions 215bc to 215bf.

By disposing the bumps 216a to 216f at positions away from the central portion O on the individual land portions 215ba to 215bf, it is possible to relax the stress to the inside of the semiconductor package 20c that is applied to the solder ball 217 when the cycle of the temperature change is repeated. Thereby, it is possible to restrain the crack in the solder ball 217.

In addition, the semiconductor package 20c in the modification 2 exerts the same effect as the semiconductor package 20a in the above-described embodiment 1.

### Modification 3

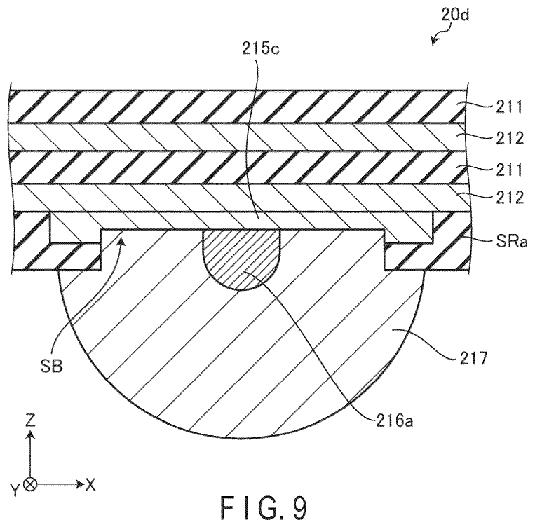

A semiconductor package 20d in a modification 3 will be described below with reference to FIG. 9. In the semiconductor package 20d in the modification 3, one bump 216a is provided on one land portion 215c. In the following description, the same constituents as those in the above-described embodiment 1 are denoted by the same reference characters, and descriptions thereof are sometimes omitted.

FIG. 9 is a diagram for describing the modification 3 of the embodiment 1. FIG. 9 is an enlarged sectional view at the height position of the solder ball 217 of the semiconductor package 20d in the modification 3 of the embodiment 1, and is a diagram corresponding to FIG. 3.

As shown in FIG. 9, one bump 216a is provided on the land portion 215c. The one bump 216a is disposed at the vicinity of the central portion of the surface SB of the land portion 215c.

The semiconductor package 20d in the modification 3 exerts the same effect as the semiconductor package 20a in the above-described embodiment 1. The configuration of the semiconductor package 20d in the modification 3 can be applied to the modifications 1 and 2.

### Modification 4

As described above, the plurality of bumps 216a and the like can be formed by the electroplating method, the wire bonding, or the like. When the bump is formed by the wire bonding, the shape may be different from the shape of the above-described bump 216a.

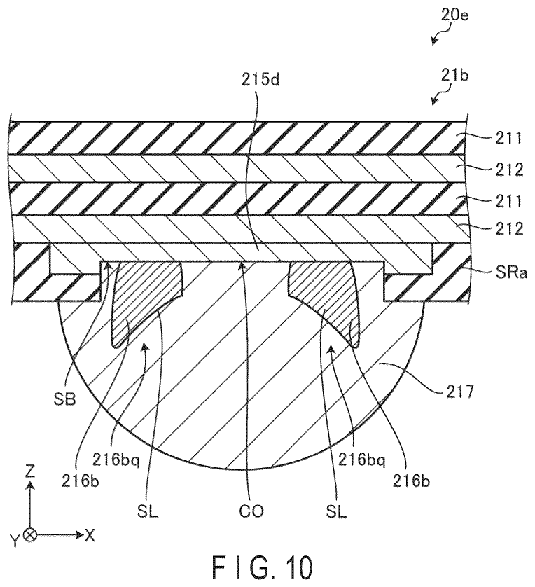

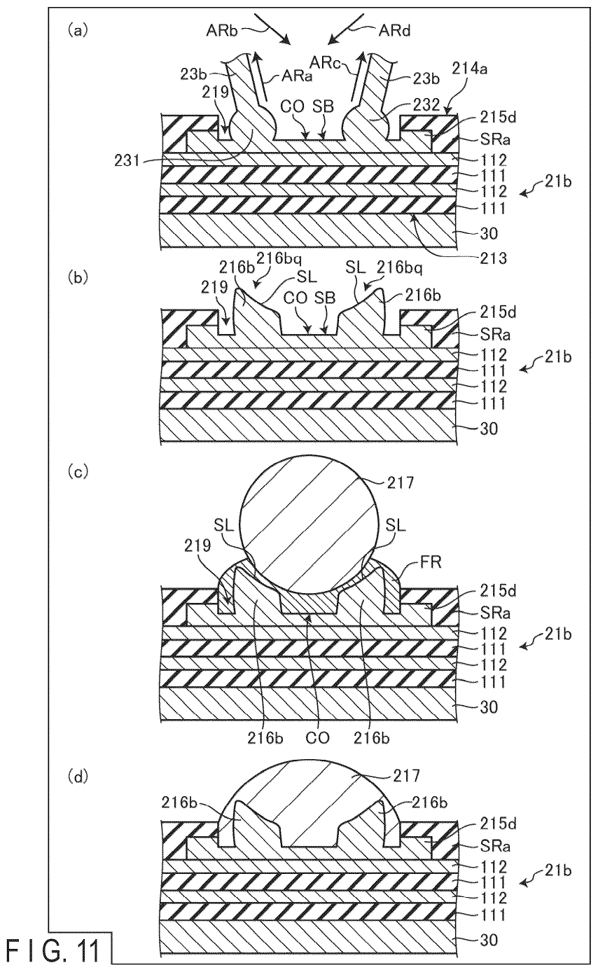

A semiconductor package 20e in a modification 4 will be described below with reference to FIG. 10 and FIG. 11. The semiconductor package 20e in the modification 4 is different from the above-described embodiment 1 in the shapes of the plurality of bumps 216b. In the following description, the same constituents as those in the above-described embodiment 1 are denoted by the same reference characters, and descriptions thereof are sometimes omitted.

FIG. 10 and FIG. 11 are diagrams for describing the modification 4 of the embodiment 1. FIG. 10 is an enlarged sectional view at the height position of the solder ball 217 of the semiconductor package 20e in the modification 4 of the embodiment 1, and is a diagram corresponding to FIG. 3.

As shown in FIG. 10, an inclined surface SL is formed at each end portion 216bq of the plurality of bumps 216b that protrudes from the surface SB of the land portion 215d. The inclined surface SL is formed so as to descend toward a central portion CO of the land portion 215d.

FIG. 11 is a diagram serially illustrating a part of the procedure of a production method for the semiconductor package 20e in the modification 4 of the embodiment 1.

In the production method for the semiconductor package 20e, before the process in the part (a) of FIG. 11, the sealing portion 30 is previously formed on the upper surface 213 of a wiring substrate 21b. In the parts (a) to (d) of FIG. 11, enlarged sectional views including the lower surface 214a of the wiring substrate 21b are shown, and some constituents such as the sealing portion 30 formed on the upper surface 213 of the wiring substrate 21b are not illustrated. Further, in the parts (a) to (d) of FIG. 11, unlike FIG. 1 and FIG. 3, for example, the lower surface 214a of the wiring substrate 21b is shown so as to be oriented upward on the sheet plane, for showing processes for the lower surface 214a of the wiring substrate 21b, as exemplified by the formation of the bump 216a and the solder ball 217.

As shown in part (a) of FIG. 11, the land portion 215d that is connected with the conductive layer 212 and whose outer edge portion is covered with the solder resist SRa is formed on the lower surface 214a of the wiring substrate 21b. The concave portion 219 whose bottom surface is the surface SB is formed at the vicinity of the central portion CO of the land portion 215d, by a predetermined treatment including the application of an organic coat such as the OSP.

Next, the plurality of bumps 216b is formed on the surface SB by the following method.

First, for the bump 216b on the left side of the sheet plane, a molten spherical portion 231 is formed by heating a distal end of a wire 23b, and the molten spherical portion 231 is crimped onto the surface SB using a capillary tool. Next, in the state where the wire 23b is clamped, the capillary tool is raised to a predetermined height in the direction of an arrow ARa.

Next, the capillary tool raised to the predetermined height is lowered toward the central portion CO of the land portion 215d in the direction of an arrow ARb, and the wire 23b is cut.

Further, the bump 216b on the right side of the sheet plane also can be formed in the same way. That is, a molten spherical portion 232 is formed by heating a distal end of a wire 23b, and the molten spherical portion 232 is crimped onto the surface SB using a capillary tool. Next, in the state where the wire 23b is clamped, the capillary tool is raised to a predetermined height in the direction of an arrow ARc.

Next, the capillary tool raised to the predetermined height is lowered toward the central portion CO of the land portion 215d in the direction of an arrow ARd, and the wire 23b is cut.

Thereby, as shown in part (b) of FIG. 11, the plurality of bumps 216b each of which has the inclined surface SL at the end portion 216bq is formed.

Next, as shown in part (c) of FIG. 11, a flux FR for the adhesion of the solder ball 217 is applied to the land portion 215d. The flux FR covers the concave portion 219 of the land portion 215d and the plurality of bumps 216b.

Next, the solder ball 217 before melting is disposed at a position that overlaps with the central portion CO, from above the flux FR. The solder ball 217 before melting is formed in a spherical shape. The solder ball 217 is stably supported by the inclined surfaces SL of the plurality of bumps 216b.

Next, the solder ball 217 is molten. Thereby, the land portion 215d and the solder ball 217 are electrically connected, and the plurality of bumps 216b is buried in the solder ball 217.

Thus, the production of the semiconductor package 20e in the modification 4 is finished.

In the semiconductor package 20e in the modification 4 and the production method for the semiconductor package 20e, the inclined surface SL that descends toward the central portion of the land portion 215 c is formed at each end portion 216bq of the plurality of bumps 216b. Thereby, when the solder ball 217 that covers the plurality of bumps 216b is formed, it is possible to stably dispose the solder ball 217 on the plurality of bumps 216b. Further, since the plurality of bumps 216b is buried in the solder ball 217, it is possible to further enhance the stopper effect with the plurality of bumps 216b.

In addition, the semiconductor package 20e in the modification 4 and the production method for the semiconductor package 20e exert the same effects as the semiconductor package 20a in the above-described embodiment and the production method for the semiconductor package 20a. The configuration of the semiconductor package 20e in the modification 4 and the production method for the semiconductor package 20e can be applied to the modifications 1 and 2.

### Embodiment 2

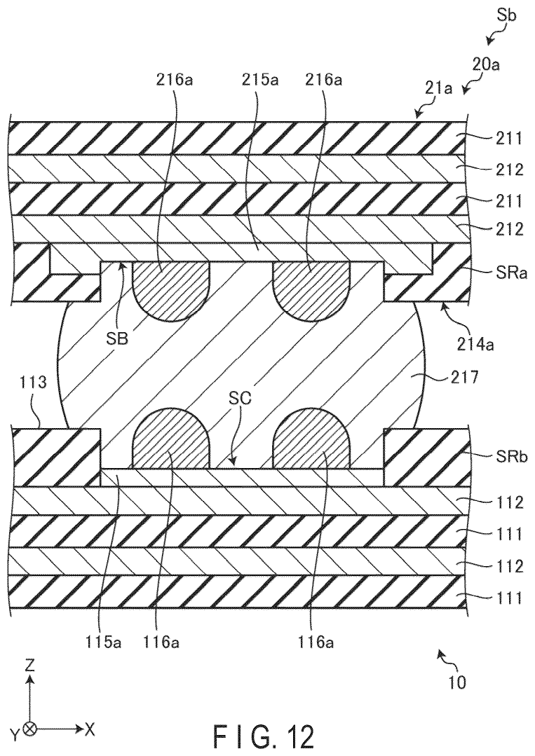

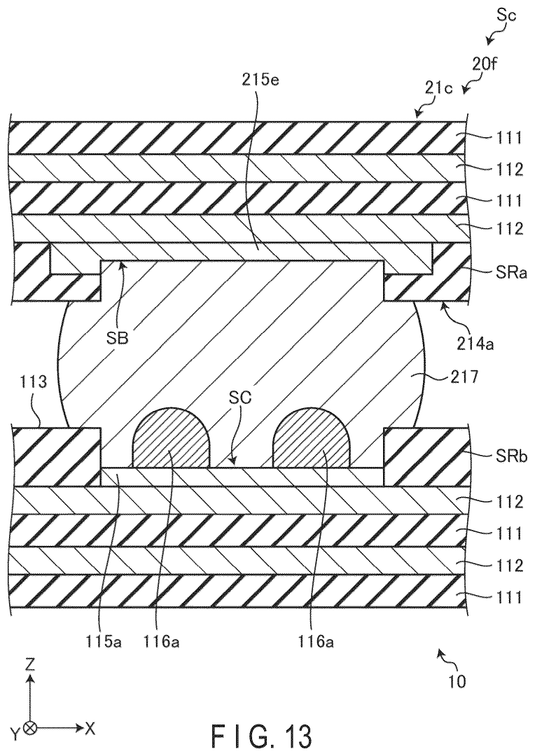

An embodiment 2 will be described below with reference to FIG. 12 and FIG. 13. In the embodiment 2, a plurality of bumps 116a is provided also on the side of a mounting substrate 10b. In the following description, the same constituents as those in the above-described embodiment and the modifications are denoted by the same reference characters, and descriptions thereof are sometimes omitted.

FIG. 12 is an enlarged sectional view showing an exemplary configuration of a part of a semiconductor system Sb in the embodiment 2. More specifically, FIG. 12 is an enlarged sectional view at the height position of the solder ball 217 of the semiconductor system Sb in the embodiment 2. The semiconductor system Sb is an example of the semiconductor device.

The semiconductor system Sb as the semiconductor device has a configuration in which the semiconductor package 20a is mounted on the mounting substrate 10b. The semiconductor package 20a and the mounting substrate 10b are connected by the solder ball 217.

The mounting substrate 10b includes a land portion 115a and a plurality of bumps 116a that protrudes from a surface SC of the land portion 115a to the positive direction in the Z-direction.

The land portion 115a is provided on the upper surface 113 of the mounting substrate 10b that is the surface that faces the wiring substrate 21a. The land portion 115a has a two-layer configuration in which a plated layer such as a Ni/Au plated layer is formed on a layer containing Cu. Therefore, in the land portion 115a, a concave portion on the surface of the land portion 115a is filled with the plated layer such as a Ni/Au plated layer that is formed after the removal of a naturally oxidized film of Cu and the like.

Each of the plurality of bumps 116a is configured to contain Cu. The diameter and height of the plurality of bumps 116a are 100 um or less, for example. The plurality of bumps 116a is buried in the solder ball 217.

The plurality of bumps 116a is disposed so as to be arrayed along the surface SC of the land portion 115a. Further, the plurality of bump 116a is disposed so as to exist on the inside of the surface SC of the land portion 115a. The individual bumps 116a are disposed at positions that respectively overlap in the top-bottom direction with the plurality of bumps 216a provided on the wiring substrate 21a. However, the individual bumps 116a do not need to respectively overlap with the plurality of bumps 216a in the top-bottom direction. Further, the number of bumps 116a that the mounting substrate 10b includes on one land portion 115a may be identical to or different from the number of bumps 216a that the wiring substrate 21a includes on one land portion 215a, and the mounting substrate 10b may include only one bump 116a on one land portion 115a.

As described above, the bumps 216a and the bumps 116a are provided on the wiring substrate 21a and the mounting substrate 10b, respectively, and thereby, it is possible to more effectively restrain the crack in the solder ball 217.

In addition, the semiconductor system Sb in the embodiment 2 exerts the same effect as the semiconductor system Sa in the above-described embodiment 1.

### Modification

A modification of the embodiment 2 will be described below with reference to FIG. 13. A semiconductor system Sc in the modification is different from the above-described embodiment 2 in that the bump 216a is not provided on the side of the wiring substrate 21b. In the following description, the same constituents as those in the above-described embodiment 2 are denoted by the same reference characters, and descriptions thereof are sometimes omitted.

FIG. 13 is a diagram for describing the modification of the embodiment 2. FIG. 13 is an enlarged sectional view at the height position of the solder ball 217 of a semiconductor package 20f in the modification, and is a diagram corresponding to FIG. 13.

As shown in FIG. 13, the mounting substrate 10b includes the land portion 115a on the upper surface 113 as a surface that faces a wiring substrate 21c. Further, the mounting substrate 10b includes the plurality of bumps 116a that protrudes from the surface SC of the land portion 115a to the positive side in the Z-direction. On the other hand, no bump is provided on a land portion 215e of the wiring substrate 21c.

The semiconductor system Sc in the modification exerts the same effect as the semiconductor systems Sa, Sb in the above-described embodiment 1 and embodiment 2.

### Other Embodiments

In the above-described embodiments and modifications, it has been described that each of the semiconductor packages 20a to 20f includes a plurality of semiconductor chips 22, but the present disclosure is not limited to this. Each of the semiconductor packages 20a to 20f may include one semiconductor chip.

In the above-described embodiments and modifications, it has been described that each of the land portions 215a to 215d is configured to contain Cu, but the present disclosure is not limited to this. Each of the land portions 215a to 215d may have a two-layer configuration in which a plated layer such as a Ni/Au plated layer is formed on a layer containing Cu. In this case, the concave portion 219 on the surface of the land portion 215a that is produced by the removal of a naturally oxidized film is filled with the plated layer such as a Ni/Au plated layer, and further, the plated layer such as a Ni/Au plated layer, as the shape, rises relative to the surface of the other portion of the land portion 215a.

Further, in the above-described embodiments and modifications, it has been described that the land portion 115a has a two-layer configuration in which the plated layer such as a Ni/Au plated layer is formed on the layer containing Cu, but the present disclosure is not limited to this. The land portion 115a may be configured as a single layer containing Cu. In this case, by the removal of a naturally oxidized film on the surface of the land portion 115a, the land portion 115a has a shape in which the vicinity of the center dents.

In the above-described embodiments and modifications, it has been described that each of the plurality of bumps 216a, 216b is configured to contain Cu, but the present disclosure is not limited to this. For example, each of the plurality of bumps 216a, 216b may be configured to contain Au, Ag, or the like.

While certain embodiments have been described, these embodiments have been presented by way of example only, and are not intended to limit the scope of the disclosure. Indeed, the novel devices and methods described herein may be embodied in a variety of other forms; furthermore, various omissions, substitutions and changes in the form of the embodiments described herein may be made without departing from the spirit of the disclosure. The accompanying claims and their equivalents are intended to cover such forms or modification as would fall within the scope and spirit of the inventions.

What is claimed is:

1. A semiconductor device comprising:
a wiring substrate including a support surface on which a semiconductor chip is to be mounted, the support surface including an electrode to be connected to the semiconductor chip, wherein
the wiring substrate includes
a first land portion on a first surface, opposite the support surface, of the wiring substrate, the first land portion being electrically connected to the electrode, the first land portion having an exposed surface opposite the first surface;
a plurality of first bumps that protrudes from the exposed surface of the first land portion; and
a solder ball on the first land portion, the solder ball burying the plurality of first bumps.

2. The semiconductor device of claim 1, wherein
each of the plurality of first bumps protruding from the exposed surface of the first land portion, the plurality of first bumps being arrayed along the exposed surface.

3. The semiconductor device of claim 2, wherein
the first land portion is a portion from which the semiconductor chip is electrically brought out, and
each of the plurality of first bumps exists on an inside of overlaps the first land portion in top view.

4. The semiconductor device of claim 1, wherein
the first land portion is one of a plurality of first land portions on the first surface of the wiring substrate in a matrix, and
the plurality of first bumps is on each of the plurality of first land portions.

5. The semiconductor device of claim 2, wherein
the first land portion is one of a plurality of first land portions on the first surface of the wiring substrate in a matrix, and
the plurality of first bumps are on each first land portion at an outer edge portion of the wiring substrate.

6. The semiconductor device of claim 5, wherein
the plurality of first bumps is on each of the first land portions at the outer edge portion, at a position away from a central portion of the first surface.

7. The semiconductor device of claim 2, wherein
each of the plurality of first bumps includes an end portion inclined toward a central portion of the first land portion.

8. The semiconductor device of claim 1, further comprising
a mounting substrate that is disposed so as to face the wiring substrate on which the semiconductor chip is placed, the mounting substrate being connected with the wiring substrate by the solder ball.

9. The semiconductor device of claim 8, wherein
the mounting substrate includes
a second land portion on a surface of the mounting substrate that faces the wiring substrate, and
a second bump that protrudes from the second land portion, wherein the solder ball buries the second bump.

10. The semiconductor device of claim 9, wherein the first bump is a plurality of first bumps protruding from the first land portion, the second bump is one of a plurality of second bumps protruding from the second land portion, and wherein each of the plurality of first bumps and the plurality of second bumps are buried in the solder ball.

11. The semiconductor device of claim 10, wherein the plurality of first bumps on the first land portion overlaps corresponding second bumps.

12. The semiconductor device of claim 1, wherein the first land portion includes a concave portion and the first bump protrudes from a bottom surface of the concave portion.

13. The semiconductor device of claim 12, wherein the solder ball buries the concave portion.

14. The semiconductor device of claim 1, wherein the exposed surface of the first land portion is recessed from the first surface.

15. The semiconductor device of claim 1, wherein each of the plurality of first bumps includes an end portion inclined toward a central portion of the first land portion.

16. A semiconductor device comprising:
a wiring substrate having a support surface on which a semiconductor chip is to be mounted;
a mounting substrate that faces the wiring substrate; and
a solder ball connecting the mounting substrate with the wiring substrate, wherein
the mounting substrate includes
a second land portion on a surface that faces the wiring substrate, and
a plurality of second bumps that protrudes from the second land portion, and
the solder ball buries the plurality of second bumps.

17. The semiconductor device of claim 16, wherein
the plurality of second bumps are arrayed along the second land portion.

18. The semiconductor device of claim 16, wherein the second land portion is recessed from a surface of the mounting substrate that faces the wiring substrate.

19. A semiconductor system, comprising:
a wiring substrate having a support surface for a semiconductor chip, the support surface including an electrode to be connected to the semiconductor chip and a first land portion on a first surface, opposite the support surface, of the wiring substrate, the first land portion being electrically connected to the electrode;
a mounting substrate including a second land portion, the second land portion of the mounting substrate facing the first land portion of the wiring substrate; and
a solder ball electrically connecting the first land portion and the second land portion, wherein
at least one of the first land portion and the second land portion includes one or more protrusions extending from a corresponding land portion, and
the solder ball buries the one or more protrusions.

20. The semiconductor system of claim 19, wherein only one of the first land portion and the second land portion includes one or more protrusions.
